(19) United States
(12) Patent Application Publication
(10) Pub. No.: US 2010/0080064 A1
(43) Pub. Date: Apr. 1, 2010

(54) BIT LINE BIAS FOR PROGRAMMING A MEMORY DEVICE

(76) Inventors: Ercole Rosario Di Iorio, Scurcola Marsicana (IT); Marco Domenico Tiburzi, Avezzano (IT)

Correspondence Address: COOL PATENT, P.C.;c/o CPA Global, P.O. BOX 52050, MINNEAPOLIS, MN, 55402, US

(21) Appl. No.: 12/242,312

(22) Filed: Sep. 30, 2008

(51) Int. Cl. G11C 16/04; G11C 16/06; G11C 7/00

(52) U.S. Cl. 365/185.19; 365/185.25; 365/185.18; 365/189.05

(57) ABSTRACT

Bit line bias for programming a memory device is generally described. In one example, circuitry for bit line bias programming comprises a word line, one or more bit lines coupled with the word line, and one or more cells to be programmed to a target threshold voltage coupled with the word line and the one or more bit lines wherein a program speed of the one or more cells is increased by selectively pre-charging the one or more bit lines such that a single program pulse raises individual threshold voltages of the one or more cells to or above the target threshold voltage.

### TECHNICAL FIELD

Embodiments disclosed herein are generally directed to the field of memory and, more particularly, to programming approaches and associated circuitry of memory devices.

### BACKGROUND

Generally, programming approaches for a memory device may include pulse programming to raise a threshold voltage of one or more cells of the memory device to a target threshold voltage. Such programming typically occurs during a programming time. Slow programming time may result in delay.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is a circuit diagram of circuitry for bit line bias programming described herein, according to but one embodiment;

FIG. 2 is a schematic of a bit line bias programming method, according to but one embodiment;

FIG. 3 is a flow diagram of a method for bit line bias programming, according to but one embodiment; and

FIG. 4 is a diagram of an example system in which circuitry for bit line bias programming as described herein may be used, according to but one embodiment.

For simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of bit line bias for programming a memory device are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout the specification to “one embodiment” or “an embodiment” means that a particular feature, structure or characteristic described in connection with the embodiment is included in at least one embodiment. Thus, appearances of the phrases “in one embodiment” or “in an embodiment” in various places throughout the specification are not necessarily referring to the same embodiment. Furthermore, the particular features, structures or characteristics may be combined in any suitable manner in one or more embodiments.

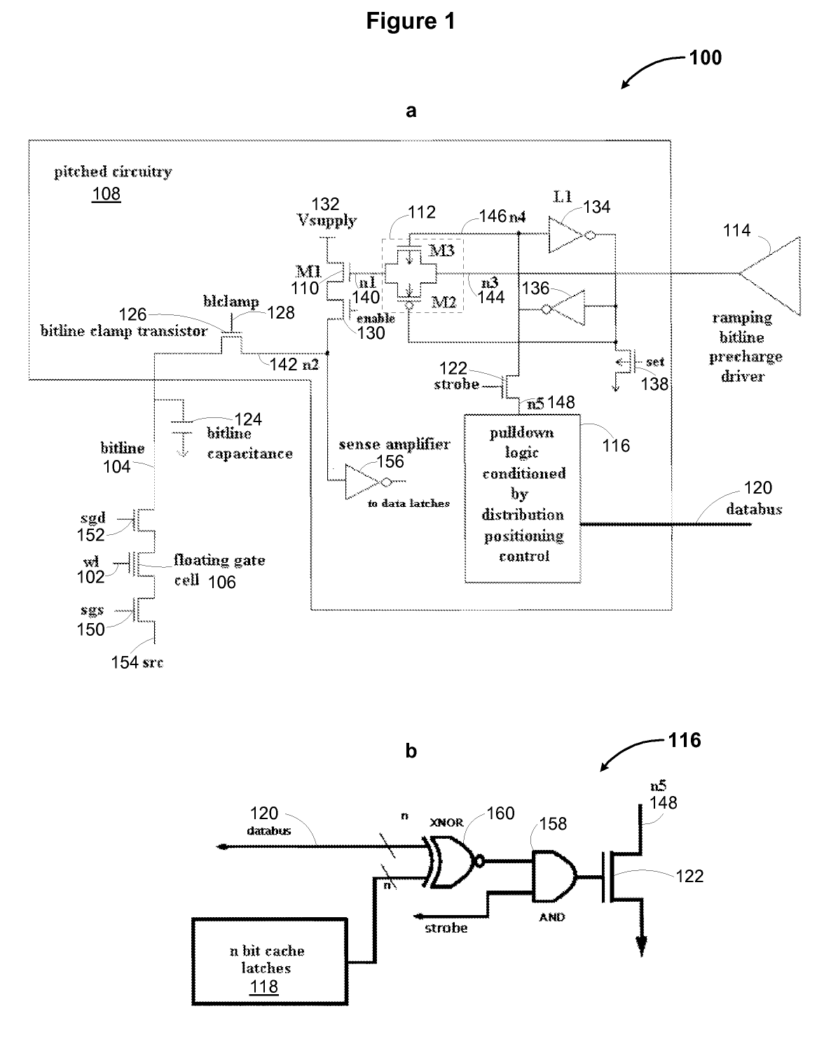

FIG. 1 is a circuit diagram of circuitry for bit line bias programming described herein, according to but one embodiment. FIG. 1 a may comprise an arrangement of circuitry 100 to allow bit line bias programming as described herein and FIG. 1b may comprise an embodiment of logic 116 used in circuitry 100. In an embodiment according to FIG. 1a, circuitry 100 comprises a word line 102, a bit line 104, a memory cell 106, and pitched circuitry 108, coupled as shown. Circuitry 100 may further comprise a capacitive gate transistor (M1) 110, transfer gate 112 comprising transistors M2 and M3, analog driver 114, logic 116, signal pathway to databus 120, strobe transistor 122, bit line capacitor 124, bit line clamp transistor 126, bit line clamp (blclamp) 128, enable transistor 130, supply voltage (Vsupply) 132, inverters 134, 136, set transistor 138, first node (n1) 140, second node (n2) 142, third node (n3) 144, fourth node (n4) 146, fifth node (n5) 148, select gate source (sgs) 150, select gate drain (sgd) 152, source (src) 154, and sense amplifier 156, coupled as shown.

In an embodiment, circuitry 100 comprises a word line 102, one or more bit lines 104 coupled with the word line 102, and one or more cells 106 to be programmed to a target threshold voltage coupled with the word line 102 and the one or more bit lines 104. Circuitry 100 may allow a program speed of the one or more cells to be increased by selectively pre-charging the one or more bit lines 104 such that a single program pulse raises individual threshold voltages of the one or more cells 106 to or above the target threshold voltage. Word line 102 may be a selected word line and one or more bit lines 104 may be coupled with the selected word line 102.

Circuitry 100 may allow pre-charging of the one or more bit lines 104 in parallel to manage the high capacitive load and bit line resistance of pre-charging the one or more bit lines 104. In an embodiment, the one or more bit lines 104 are arranged such that selectively pre-charging the one or more bit lines 104 comprises independently biasing the one or more bit lines 104 in parallel. Pitched circuitry 108 may allow a user of a memory device to store information such as digital information in pitched circuitry 108 to program the one or more memory cells 106. Digital information may be stored, for example, in data cache or data latches 118 coupled with logic 116. In an embodiment, a unique data cache or data latch 118 is coupled to each individual bit line of the one or more bit lines 104, the data latches 118 being loaded serially by a chip digital port (not shown), which may be a system of a memory chip to load the data latches 118.

A capacitive gate transistor M1 110 may be coupled with the one or more bit lines 104 to store an analog voltage to selectively pre-charge the one or more bit lines 104. In an embodiment, the capacitive gate transistor M1 110 is a sufficiently high capacitive gate transistor M1 110 to pre-charge the one or more bit lines 104 in parallel. The stored analog voltage on capacitive gate transistor M1 110 may be used to selectively pre-charge the one or more bit lines 104 according to digital information provided by a user.

Circuitry 100 may further comprise a transfer gate 112 coupled with the capacitive gate transistor M1 110, an analog driver 114 coupled with the transfer gate 112, logic 116 coupled with the transfer gate 112, and a data latch 118 coupled with the logic 116 to store information. Data cache or latches 118 may be coupled with the one or more bit lines 104 to store values of the individual threshold voltages of the one or more cells 106. In an embodiment, the gate of the capacitive gate transistor 110 is charged up through the analog driver 114 using the transfer gate 112 that is driven by the data latch 118 coupled with the logic 116 prior to applying a program pulse to the one or more cells 106.

Circuitry 100 may further comprise a first node n1 140 coupled with a gate of the capacitive gate transistor M1 110 and also coupled with the transfer gate 112 wherein the data latch 118 is reset and the analog voltage of the analog driver 114 is stored on the first node n1 140 when the logic 116 determines that the individual threshold voltages of the one or more cells have reached or surpassed the target threshold voltage. The stored analog voltage on first node n1 140 may remain substantially constant until a subsequent program verify operation is performed.

In an embodiment, analog driver 114 is a ramping bit line pre-charge driver that provides an analog voltage to the capacitive gate transistor 110. In an embodiment, the driver 114 provides an analog voltage comprising a threshold voltage of an n-type metal-oxide-semiconductor (NMOS) transistor wherein the analog voltage provided by the driver 114 is kept substantially constant by the gate capacitance of the capacitive gate transistor 110.

Logic 116 may comprise pulldown logic conditioned by distribution positioning control. In one embodiment according to FIG. 1b, distribution positioning control logic 116 comprises transistor 122, fifth node n5 148, NAND gate 158, NOR gate 160, data latches 118, and signal pathway to databus 120, coupled as shown.

A latch supply voltage 132 may turn off M2 transistor of transfer gate 112 and may also provide supply voltage for inverters 134, 136. In an embodiment, M2 transistor of transfer gate 112 is a p-type metal-oxide semiconductor (PMOS) transistor. In an embodiment, a latch supply voltage 132 applied to first node n1 140, V(n1), is equal to a voltage of second node n2 142, V(n2) plus a threshold voltage of an NMOS transistor M1 110, Vtn, to pass a voltage on the second node n2 142. In another embodiment, a gate voltage of at least a threshold voltage of a PMOS transistor that is higher than a voltage of first node n1 140, V(n1), is applied to the gate of the M2 transistor of transfer gate 112 to turn it off. In other embodiments, M1 transistor 110 may be in other arrangements including arrangements with low threshold voltage transistors or depleted transistors. In other embodiments, circuitry 100 comprises a rail to rail bit line driver using mirror arrangement with a PMOS cascode that is able to regulate 0 V with a negative voltage on its gate.

Embodiments disclosed herein may apply to arrangements that use sample and hold techniques. In an embodiment, circuitry 100 comprises sample and hold circuitry coupled with the one or more bit lines 104. Circuitry 100 may allow selective programming of one or more cells 106 coupled with a selected word line 102. Circuitry 100 may allow a program pulse to be set to a higher voltage, thus reducing program disturb and programming time. In an embodiment, a duration of a program pulse allows sufficient time to refresh a voltage stored on cascode M1 110 to accommodate high leakage current transistor technologies.

In an embodiment, one or more cells 106 are memory cells of a NAND flash memory array. Embodiments disclosed herein may not be limited to NAND flash memory applications and may include other suitable technologies in other embodiments.

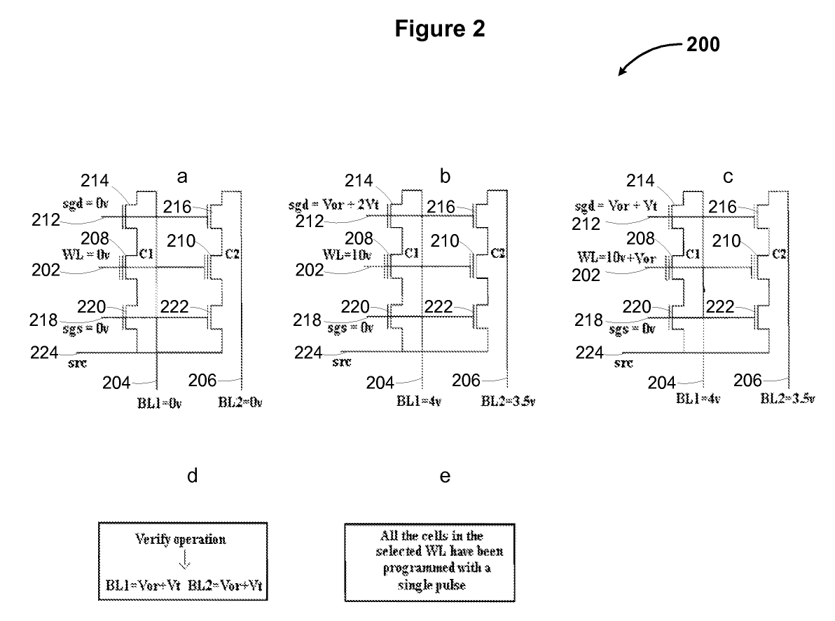

FIG. 2 is a schematic of a bit line bias programming method, according to but one embodiment. In an embodiment, schematic 200 is used to describe a bit line bias programming method comprising a word line (WL) 202, first bit line (BL1) 204, second bit line (BL2) 206, first memory cell (C1) 208, second memory cell (C2) 210, select gate drain (sgd) 212, select gate drain transistors 214, 216, select gate source (sgs) 218, select gate source transistors 220, 222, and source line (src) 224, coupled as shown.

In an embodiment according to FIG. 2a, information such as digital information is stored to program one or more memory cells 208, 210. One or more bit lines 204, 206 may be coupled with the one or more memory cells 208, 210. In an embodiment, a first bit line BL1 204 is coupled with a first memory cell C1 208 and a second bit line BL2 206 is coupled with a second memory cell C2 210. First bit line BL1 204 and second bit line BL2 206 may be coupled with pitched circuitry 108 described with respect to FIG. 1. A world line WL 202 may be coupled with the first and second memory cells 208, 210. Word line WL 202 may be selected for programming first and second memory cells 208, 210. More cells than first memory cell C1 208 may be coupled with first bit line BL1 204 and more cells than second memory cell C2 210 may be coupled with second bit line BL2 206.

A select gate drain sgd 212 may be coupled with one or more select gate drain transistors 214, 216, which may be coupled with the first bit line BL1 204 and the second bit line BL2 206 respectively. Select gate drain sgd 212 may comprise a control signal to connect the drain side of the memory cells 208, 210 in a single block to their respective bit lines 204, 206. A select gate source sgs 218 may be coupled with one or more select gate source transistors 220, 222, which may be coupled with the first bit line BL1 204 and the second bit line BL2 206 respectively. Select gate source sgs 218 may be a control signal to connect the source side of memory cells 208, 210 in a single block wherein the block is an independently erasable array portion. A source line src 224 may be coupled with the source side of the memory cells 208, 210. Source line SRC 224 may be coupled to a source terminal of the memory cells 208, 210 and may be common to all memory cells 208, 210 in a memory cell array.

In an embodiment, information to be programmed to the one or more memory cells 208, 210 is stored in a data cache prior to selectively pre-charging the one or more bit lines 204, 206. Data cache may be coupled with the one or more bit lines 204, 206. For example, a data cache may be coupled with the one or more bit lines 204, 206 according to arrangements depicted with respect to FIG. 1. Other configurations may be used in other embodiments. Information may include digital information such as one or more bits of information.

In one embodiment, word line WL 202, first bit line BL1 204, second bit line BL2 206, select gate drain 212, and select gate source comprise a voltage of about 0 V when information is stored in the data cache. A first individual threshold voltage (Vt_{C1}) for first memory cell may comprise a voltage of about −1 V and a second individual threshold voltage (Vt_{C2}) for second memory cell may comprise a voltage of about −1 V. Other voltages may be used in other embodiments.

In an embodiment according to FIG. 2b, one or more bit lines 204, 206 are selectively pre-charged prior to applying a program pulse. A pre-charge circuit may be activated to commence selective pre-charging of the one or more bit lines 204, 206. A bias voltage may be applied to the one or more bit lines 204, 206 to pre-charge the one or more bit lines 204, 206. In an embodiment, a bias voltage of about 4 V is applied to first bit line BL1 204 and a bias voltage of about 3.5 V is applied to second bit line BL2 206. Word line WL 202 may comprise a voltage of about 10 V and select gate drain sgd 212 may comprise a voltage of about Vor+2 Vt where Vor is an operating voltage range, which may be used to define an upper limit value reachable by individual threshold voltages Vt_{C1} and Vt_{C2} after a program operation and where Vt is a threshold voltage of the select gate drain device 214. Select gate source sgs 218 may comprise a voltage of about 0 V. The first individual threshold voltage, Vt_{C1}, for first memory cell may comprise a voltage of about −1 V and a second individual threshold voltage, Vt_{C2}, for second memory cell may comprise a voltage of about −1 V.

In an embodiment according to FIG. 2c, a program pulse is applied to the one or more memory cells 208, 210 after selectively pre-charging the one or more bit lines 204, 206. In an embodiment, a program pulse is applied to the one or more memory cells 208, 210 while a bias voltage is applied to the one or more bit lines 204, 206. In an embodiment, a bias voltage of about 4 V is applied to first bit line BL1 204 and a bias voltage of about 3.5 V is applied to second bit line BL2 206. Word line WL 202 may comprise a voltage of about 10 V+Vor where Vor is the operating voltage range. The select gate drain sgd 212 may comprise a voltage of about Vor+Vt where Vor is the operating voltage range and where Vt is the threshold voltage of the select gate drain device 214. The select gate source sgs 218 may comprise a voltage of about 0 V. The first individual threshold voltage, Vt_{C1}, for first memory cell may comprise a voltage of about 0 V and a second individual threshold voltage, Vt_{C2}, for second memory cell may comprise a voltage of about 500 mV.

In an embodiment according to FIG. 2d, a verify operation is performed to determine whether the one or more cells 208, 210 have reached or surpassed the target threshold voltage of the one or more cells 208, 210. Verifying may comprise sensing the one or more cells after applying the program pulse. If individual threshold voltages of the one or more cells 208, 210 have reached or surpassed the target threshold voltage after applying a single program pulse, then all the cells of the selected word line 202 have been programmed with the single pulse as described in FIG. 2e. An inhibiting voltage may be applied to the memory cells 208, 210 to prevent further programming after reaching the target threshold voltage. In an embodiment, an inhibiting voltage comprises a voltage of Vor+Vt applied to BL1 204 for first memory cell 208 and a voltage of Vor+Vt applied to BL2 206 for second memory cell 210.

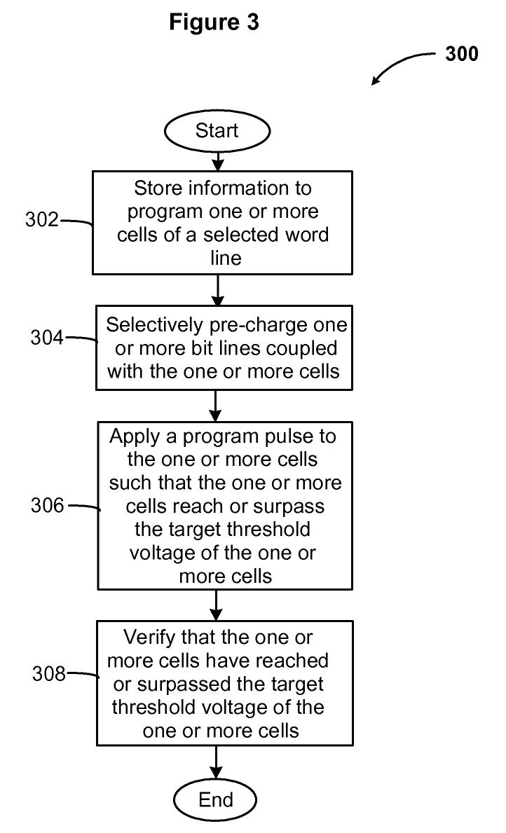

FIG. 3 is a flow diagram of a method for bit line bias programming, according to but one embodiment. In an embodiment, method 300 includes storing information to program one or more cells of a selected word line at box 302, selectively pre-charging one or more bit lines coupled with the one or more cells at box 304, applying a program pulse to the one or more cells such that the one or more cells reach or surpass the target threshold voltage of the one or more cells at box 306, and verifying that the one or more cells have reached or surpassed the target threshold voltage of the one or more cells at box 308. Storing information to program one or more cells 302 may include storing information such as digital information in a data cache to be programmed to the one or more cells of the selected word line. Storing information in the data cache 302 may occur prior to selectively pre-charging the one or more bit lines 304.

In an embodiment, method 300 includes selectively pre-charging one or more bit lines coupled with one or more cells of a selected word line that are to be programmed 304 and applying a single program pulse comprising a program voltage to the one or more cells 306. The program voltage may be greater than another program voltage used for a program algorithm that uses multiple pulses to program the one or more cells. In an embodiment, selectively pre-charging the one or more bit lines 304 allows individual threshold voltages of the one or more cells to reach or surpass a target threshold voltage by application of the single program pulse 306.

Selectively pre-charging the one or more bit lines 304 may include sensing the one or more cells of the selected word line that are to be programmed to determine initial values of the individual threshold voltages (Vtᵢₙᵢₜᵢₐₗ). Selectively pre-charging the one or more bit lines 304 may further include applying an individual pre-charge voltage (V_{bitline}) to the one or more bit lines based on the initial values of the individual threshold voltages, Vtᵢₙᵢₜᵢₐₗ, wherein V_{bitline} is sufficient to allow the individual threshold voltages of the one or more cells to reach or surpass the target threshold voltage (Vt_{final}) by application of the single program pulse. The individual pre-charge voltage, V_{bitline}, for a particular bit line may be different from the individual pre-charge voltage for another particular bit line. Individual pre-charge voltage, V_{bitline}, may be determined according to the following relationship where V_{bitline} is the individual pre-charge voltage to be applied to the one or more bit lines, V_{delta} is a stepping voltage to be applied to a gate of the one or more cells while applying the single program pulse, Vt_{final} is the target threshold voltage of the one or more cells, and Vtᵢₙᵢₜᵢₐₗ is the initial value of the individual threshold voltage of the one or more cells:

V_{bitline}=V_{delta}−(Vt_{final}+Vtᵢₙᵢₜᵢₐₗ) [1]

In an embodiment, method 300 includes storing initial values of the individual threshold voltages of the one or more cells in a data cache. In such embodiment, selectively pre-charging the one or more bit lines further comprises storing an analog voltage on a capacitive gate transistor to selectively pre-charge the one or more bit lines 304 according to the initial values of the individual threshold voltages (Vtᵢₙᵢₜᵢₐₗ) stored in the data cache. A capacitive gate transistor may be a higher capacitive gate transistor wherein the capacitance is between about 50 femto-farads (fF) and about 100 fF.

Selectively pre-charging the one or more bit lines 304 may includes independently biasing the one or more bit lines. The bit lines may be pre-charged in parallel to manage a high capacitive load and bit line resistance of pre-charging the one or more bit lines 304. Selectively pre-charging the one or more bit lines 304 may increase the program speed of a memory device by reducing a number of program pulses to program the memory device. Such benefit may reduce programming time of a memory device.

Method 300 may include verifying that the one or more cells have reached or surpassed the target threshold voltage of the one or more cells 306. In an embodiment, verifying the one or more cells 306 comprises verifying that the individual threshold voltages of the one or more cells have reached or surpassed the target threshold voltage by sensing the one or more cells after applying the single program pulse.

Method 300 may include embodiments already described with respect to FIGS. 1-2. Various operations may be described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

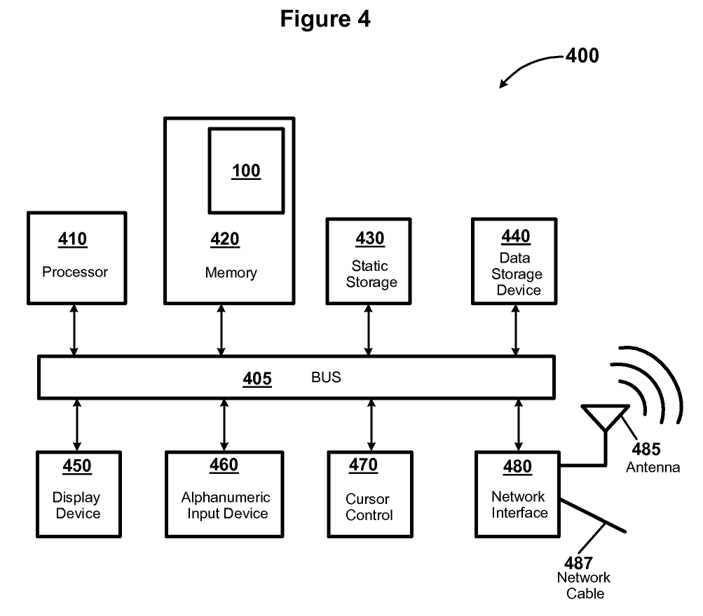

FIG. 4 is a diagram of an example system in which circuitry for bit line bias programming as described herein may be used, according to but one embodiment. System 400 is intended to represent a range of electronic systems (either wired or wireless) including, for example, desktop computer systems, laptop computer systems, personal computer (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

Electronic system 400 may include bus 405 or other communication device to communicate information, and processor 410 coupled to bus 405 that may process information. While electronic system 400 is illustrated with a single processor, system 400 may include multiple processors and/or co-processors. System 400 may also include random access memory (RAM) or other storage device 420 (referred to as memory), coupled to bus 405 and may store information and instructions that may be executed by processor 410.

Memory 420 may also be used to store temporary variables or other intermediate information during execution of instructions by processor 410. In one embodiment, memory 420 includes circuitry 100 for bit line bias programming as described herein. Memory 420 is a flash memory device in one embodiment.

System 400 may also include read only memory (ROM) and/or other static storage device 430 coupled to bus 405 that may store static information and instructions for processor 410. Data storage device 440 may be coupled to bus 405 to store information and instructions. Data storage device 440 such as a magnetic disk or optical disc and corresponding drive may be coupled with electronic system 400.

Electronic system 400 may also be coupled via bus 405 to display device 450, such as a cathode ray tube (CRT) or liquid crystal display (LCD), to display information to a user. Alphanumeric input device 460, including alphanumeric and other keys, may be coupled to bus 405 to communicate information and command selections to processor 410. Another type of user input device is cursor control 470, such as a mouse, a trackball, or cursor direction keys to communicate information and command selections to processor 410 and to control cursor movement on display 450.

Electronic system 400 further may include one or more network interfaces 480 to provide access to network, such as a local area network. Network interface 480 may include, for example, a wireless network interface having antenna 485, which may represent one or more antennae. Network interface 480 may also include, for example, a wired network interface to communicate with remote devices via network cable 487, which may be, for example, an Ethernet cable, a coaxial cable, a fiber optic cable, a serial cable, or a parallel cable.

In one embodiment, network interface 480 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 400 includes one or more omnidirectional antennae 485, which may refer to an antenna that is at least partially omnidirectional and/or substantially omnidirectional, a processor 410 coupled to communicate via the antennae, and memory 420 comprising circuitry 100 for bit line bias programming as described herein coupled with the processor. According to various embodiments, memory device 420 accords with embodiments described with respect to FIGS. 1-3.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of the description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. An apparatus comprising:
a word line;
one or more bit lines coupled with the word line; and
one or more cells to be programmed to a target threshold voltage coupled with the word line and the one or more bit lines wherein a program speed of the one or more cells is increased in response to selective pre-charging of the one or more bit lines such that a single program pulse raises individual threshold voltages of the one or more cells to or above the target threshold voltage.

2. An apparatus according to claim 1 further comprising:
a capacitive gate transistor coupled with the one or more bit lines to store an analog voltage to selectively pre-charge the one or more bit lines.

3. An apparatus according to claim 2 further comprising:
a transfer gate coupled with the capacitive gate transistor;
an analog driver coupled with the transfer gate, the analog driver to provide the analog voltage to the capacitive gate transistor wherein the analog voltage is kept substantially constant by the capacitive gate transistor;
logic coupled with the transfer gate; and
a data latch coupled with the logic to store information wherein a gate of the capacitive gate transistor is charged up through the analog driver using the transfer gate that is driven by the data latch coupled with the logic prior to applying the single program pulse.

4. An apparatus according to claim 2 further comprising:
a data cache coupled with the one or more bit lines to store values of the individual threshold voltages (Vtᵢₙᵢₜᵢₐₗ) of the one or more cells wherein a capacitance of the capacitive gate transistor is between about 50 femtofarads (fF) and about 100 fF.

5. An apparatus according to claim 1 wherein the one or more bit lines are arranged such that selectively pre-charging the one or more bit lines comprises independently biasing the one or more bit lines in parallel.

6. An apparatus according to claim 2 further comprising:
a transfer gate coupled with the capacitive gate transistor;
an analog driver coupled with the transfer gate to provide the analog voltage;
logic coupled with the transfer gate;
a data latch coupled with the logic to store information; and
a first node coupled with a gate of the capacitive gate transistor and coupled with the transfer gate wherein the data latch is reset and the analog voltage of the analog driver is stored on the first node in response to the logic determining that the individual threshold voltages of the one or more cells have reached or surpassed the target threshold voltage.

7. An apparatus according to claim 1 further comprising:
sample and hold circuitry coupled with the one or more bit lines.

8. A method comprising:
selectively pre-charging one or more bit lines coupled with one or more cells of a selected word line that are to be programmed; and
applying a single program pulse comprising a program voltage to the one or more cells wherein selectively pre-charging the one or more bit lines allows individual threshold voltages of the one or more cells to reach or surpass a target threshold voltage by application of the single program pulse.

9. A method according to claim 8 wherein selectively pre-charging the one or more bit lines comprises:
sensing the one or more cells of the selected word line that are to be programmed to determine initial values of the individual threshold voltages (Vtᵢₙᵢₜᵢₐₗ) of the one or more cells;
applying an individual pre-charge voltage (V_{bitline}) to the one or more bit lines based on the initial values of the individual threshold voltages (Vtᵢₙᵢₜᵢₐₗ) wherein _{bitline} is sufficient to allow the individual threshold voltages of the one or more cells to reach or surpass the target threshold voltage (Vt_{final}) by application of the single program pulse.

10. A method according to claim 9 wherein the individual pre-charge voltage (V_{bitline}) is determined by the following relationship where V_{bitline} is the individual pre-charge voltage to be applied to the one or more bit lines, V_{delta} is a stepping voltage to be applied to a gate of the one or more cells while applying the single program pulse, Vt_{final} is the target threshold voltage of the one or more cells, and Vtᵢₙᵢₜᵢₐₗ is the initial value of the individual threshold voltage of the one or more cells:
V_{bitline}=V_{delta}−(Vt_{final}+Vtᵢₙᵢₜᵢₐₗ).

11. A method according to claim 9 further comprising:
storing initial values of the individual threshold voltages (Vtᵢₙᵢₜᵢₐₗ) of the one or more cells in a data cache wherein selectively pre-charging the one or more bit lines further comprises storing an analog voltage on a capacitive gate transistor to selectively pre-charge the one or more bit lines according to the initial values of the individual threshold voltages (Vtᵢₙᵢₜᵢₐₗ) stored in the data cache.

12. A method according to claim 8 wherein selectively pre-charging the one or more bit lines comprises independently biasing the one or more bit lines in parallel and wherein selectively pre-charging the one or more bit lines increases program speed of a memory device by reducing a number of program pulses to program the memory device.

13. A method according to claim 8 wherein the program voltage is greater than another program voltage used for a program algorithm that uses multiple pulses to program the one or more cells.

14. A method according to claim 8 further comprising:
storing information in a data cache to be programmed to the one or more cells of the selected word line wherein storing the information in the data cache occurs prior to selectively pre-charging the one or more bit lines.

15. A method according to claim 8 further comprising:
verifying that the individual threshold voltages of the one or more cells have reached or surpassed the target threshold voltage by sensing the one or more cells after applying the single program pulse.
